(19) United States
(12) Patent Application Publication
(10) Pub. No.: US 2025/0118602 A1
(43) Pub. Date: Apr. 10, 2025

(54) METROLOGY SYSTEM WITH TWIN PLANAR MOTOR STAGE

(71) Applicant: KLA Corporation, Milpitas, CA (US)

(72) Inventors: Michel Pharand, Los Gatos, CA (US); Phalguna Rachinayani, San Jose, CA (US)

(21) Appl. No.: 18/437,429

(22) Filed: Feb. 9, 2024

Related U.S. Application Data
(60) Provisional application No. 63/543,506, filed on Oct. 10, 2023.

(51) Int. Cl. H01L 21/66; G01R 33/07; H01L 21/677; H02K 1/18; H02K 1/2783

(52) U.S. Cl. CPC H01L 22/12; G01R 33/07; H01L 21/67739; H01L 22/34; H02K 1/185; H02K 1/2783

(57) ABSTRACT

A system includes a stator, and a first carrier and a second carrier disposed over a horizontal surface of the stator. A plurality of electromagnetic coils are disposed in an array beneath the horizontal surface. The first carrier and the second carrier each include plurality of magnets arranged in an array and are configured to support a first substrate and a second substrate, respectively. A controller is configured to individually energize each of the plurality of electromagnetic coils, which causes the first carrier and the second carrier to levitate above the horizontal surface and independently move in a loop relative to the horizontal surface. The plurality of electromagnetic coils can apply a differential force to adjust a planar alignment of the first substrate or the second substrate, and a metrology tool can take one or more measurements of the first substrate or the second substrate.

### CROSS-REFERENCE TO RELATED APPLICATIONS

This application claims priority to the provisional patent application filed Oct. 10, 2023, and assigned U.S. App. No. 63/543,506, the disclosure of which is hereby incorporated by reference.

### FIELD OF THE DISCLOSURE

This disclosure relates to semiconductor metrology systems and, more particularly, to a metrology system having wafer alignment correction.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices, such as logic and memory devices, typically includes processing a semiconductor wafer using a large number of fabrication processes to form various features and multiple levels of the semiconductor devices. For example, lithography is a semiconductor fabrication process that involves transferring a pattern from a reticle to a photoresist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Metrology processes are used at various steps during semiconductor manufacturing to monitor and control the process. Metrology processes are different than inspection processes in that, unlike inspection processes in which defects are detected on wafers, metrology processes are used to measure one or more characteristics of the wafers that cannot be determined using existing inspection tools. Metrology processes can be used to measure one or more characteristics of wafers such that the performance of a process can be determined from the one or more characteristics. For example, metrology processes can measure a dimension (e.g., line width, thickness, etc.) of features formed on the wafers during the process. In addition, if the one or more characteristics of the wafers are unacceptable (e.g., out of a predetermined range for the characteristic(s)), the measurements of the one or more characteristics of the wafers may be used to alter one or more parameters of the process such that additional wafers manufactured by the process have acceptable characteristic(s).

The accuracy of metrology and inspection processes may depend on the planar alignment of the wafer and the presence of any local wafer tilt. Wafer tilt can develop based on mechanical limitations of the system holding the wafer or from wafer related properties such as thickness gradients or backside particles. In the present wafer tilt, systems may perform correction by manipulating the stage based on feedback from a pre-mapped stage or active measurement of local tilt. The local tilt is either measured or computed (from a stored map) and the stage is adjusted such that this tilt (in two orthogonal planes) is removed. However, these processes are performed on a single stage, in which wafer alignment and metrology is done serially on a single wafer before processing another wafer. Accordingly, repeated alignment and metrology steps reduce throughput and increase operation cost.

Therefore, what is needed is a metrology system with wafer alignment correction having improved throughput and operation cost.

### BRIEF SUMMARY OF THE DISCLOSURE

An embodiment of the present disclosure provides a system. The system may comprise a stator comprising a horizontal surface and a plurality of electromagnetic coils disposed in an array beneath the horizontal surface. The system may further comprise a first carrier and a second carrier disposed over the horizontal surface of the stator. The first carrier and the second carrier may each comprise plurality of magnets arranged in an array, and the first carrier and the second carrier may be configured to support a first substrate and a second substrate, respectively.

The system may further comprise a controller configured to individually energize each of the plurality of electromagnetic coils. Energizing at least some of the plurality of electromagnetic coils may cause the first carrier and the second carrier to levitate above the horizontal surface and independently move in a loop relative to the horizontal surface. An alignment station and a measurement station may each define separate areas of the horizontal surface in the loop. The controller may be further configured to energize at least some of the plurality of electromagnetic coils to apply a differential force to the first carrier or the second carrier to adjust a planar alignment of the first substrate or the second substrate relative to the horizontal surface when the first carrier or the second carrier is positioned at the alignment station. The controller may be further configured to control a metrology tool to take one or more measurements of the first substrate or the second substrate when the first carrier or the second carrier is positioned at the measurement station.

In some embodiments, the plurality of magnets may be arranged in a Halbach array.

In some embodiments, the system may further comprise a vacuum pump. The first carrier and the second carrier may be configured to hold the first substrate or the second substrate by vacuum pressure from the vacuum pump.

In some embodiment, the first carrier and the second carrier may each further comprise surface features defined on a top surface beneath the first substrate or the second substrate; a plurality of openings disposed between the surface features; and a distribution channel in fluid communication with the plurality of openings. The vacuum pump may be connected to the distribution channel by a flexible cable and may be configured to draw air from the top surface of the first carrier and the second carrier via the surface features, the plurality of openings, and the distribution channel, through a pneumatic line in the flexible cable.

In some embodiments, the stator may further comprise a plurality of Hall effect sensors arranged in an array beneath the horizontal surface. The plurality of Hall effect sensors may be configured to track the position of the first carrier and the second carrier relative to the horizontal surface. The plurality of Hall effect sensors may be configured to track the position of the first carrier and the second carrier based on proximity of the plurality of magnets of the first carrier and the second carrier to at least one of the plurality of Hall effect sensors.

In some embodiments, the controller may be further configured to determine whether the first carrier or the second carrier is positioned at the measurement station based on position information received from the plurality of Hall effect sensors. The controller may be further configured to control a metrology tool to take one or more measurements of the first substrate when the first carrier is determined to be positioned at the measurement station. The controller may be further configured to control the metrology tool to take one or more measurements of the second substrate when the second carrier is determined to be positioned at the measurement station.

In some embodiments, the metrology tool may be configured to capture measurements based on at least one of reflectometry, spectroscopy, ellipsometry, image data.

In some embodiments, the system may further comprise a handling robot. The handling robot may be configured to load the first substrate on the first carrier when the first carrier is positioned at a load station; and load the second substrate on the second carrier when the second carrier is positioned at the load station.

In some embodiments, the load station may define an area of the horizontal surface in the loop separate from the alignment station and the measurement station. The controller may be further configured to: determine whether the first carrier or the second carrier is positioned at the load station based on position information received from the plurality of Hall effect sensors; and energize at least some of the plurality of electromagnetic coils to move the first carrier and the second carrier in the loop from the load station to the alignment station or the measurement station.

In some embodiments, the load station may be the alignment station.

In some embodiments, the handling robot may be further configured to: unload the first substrate from the first carrier when the first carrier is positioned at an unload station; and unload the second substrate from the second carrier when the second carrier is positioned at the unload station.

In some embodiments, the unload station may define an area of the horizontal surface separate from the alignment station and the measurement station. The controller may be further configured to: energize at least some of the plurality of electromagnetic coils to move the first carrier and the second carrier in the loop from the alignment station or the measurement station to the unload station; and determine whether the first carrier or the second carrier is positioned at the unload station based on the position information received from the plurality of Hall effect sensors.

In some embodiments, the unload station may be the measurement station.

In some embodiments, the unload station may be the load station.

In some embodiments, the controller may be further configured to control an interferometer to measure the planar alignment of the first substrate or the second substrate when the first carrier or the second carrier are positioned at the alignment station. The controller may be further configured to: determine the planar alignment of the first substrate or the second substrate based on alignment information received from the interferometer; and energize at least some of the plurality of electromagnetic coils to apply the differential force to the first carrier or the second carrier to adjust the planar alignment of the first substrate or the second substrate to an adjusted planar alignment.

In some embodiments, the first substrate and the second substrate may remain in the adjusted planar alignment when moved in the loop from the alignment station to the measurement station.

Another embodiment of the present disclosure provides a method. The method may comprise loading a first substrate on a first carrier and a second substrate on a second carrier. The first carrier and the second carrier may each comprise plurality of magnets arranged in an array, and the first carrier and the second carrier may be disposed over a horizontal surface of a stator.

The method may further comprise energizing a plurality of electromagnetic coils disposed in an array beneath the horizontal surface to cause the first carrier and the second carrier to levitate above the horizontal surface and independently move in a loop relative to the horizontal surface. A measurement station and an alignment station may each define separate areas of the horizontal surface in the loop.

The method may further comprise energizing at least some of the plurality of electromagnetic coils to apply a differential force to the first carrier or the second carrier to adjust a planar alignment of the first substrate or the second substrate relative to the horizontal surface when the first carrier or the second carrier is positioned at the alignment station.

The method may further comprise controlling a metrology tool to take one or more measurements of the first substrate or the second substrate when the first carrier or the second carrier is positioned at the measurement station.

In some embodiments, the first substrate may be loaded on the first carrier before the second substrate is loaded on the second carrier, and the second substrate may be loaded on the second carrier while the first carrier is positioned at the alignment station or the measurement station.

### DESCRIPTION OF THE DRAWINGS

For a fuller understanding of the nature and objects of the disclosure, reference should be made to the following detailed description taken in conjunction with the accompanying drawings, in which:

FIG. 1 is a cross-sectional side view of a system according to an embodiment of the present disclosure;

FIG. 2 is a top view of a system according to an embodiment of the present disclosure;

FIG. 3A is a cross-sectional top view of a stator of a system according to an embodiment of the present disclosure;

FIG. 3B is a cross-sectional top view of a stator of a system according to another embodiment of the present disclosure;

FIG. 4A is a cross-sectional top view of a carrier of a system according to an embodiment of the present disclosure;

FIG. 4B is a top view of the carrier of FIG. 4A;

FIG. 4C is another cross-sectional top view of the carrier of FIG. 4A, above the section plane of FIG. 4A;

FIGS. 5A-5H are top views of a series of stations in the loop according to embodiments of the present disclosure; and

FIG. 6 is a flowchart of a method according to an embodiment of the present disclosure.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

An embodiment of the present disclosure provides a system 100. The system 100 may be an inspection system or a metrology system. The system 100 may be configured to perform one or more processing steps on a workpiece. The workpiece may be a semiconductor wafer, substrate, printed circuit board, panel, or other object processed by the system 100. The workpiece may move between one or more stations of the system 100 to be processed. For example, the system 100 may use magnetic levitation to transport the workpiece between the stations for processing. Such systems 100 utilizing planar motors to levitate and move the workpiece are further described herein.

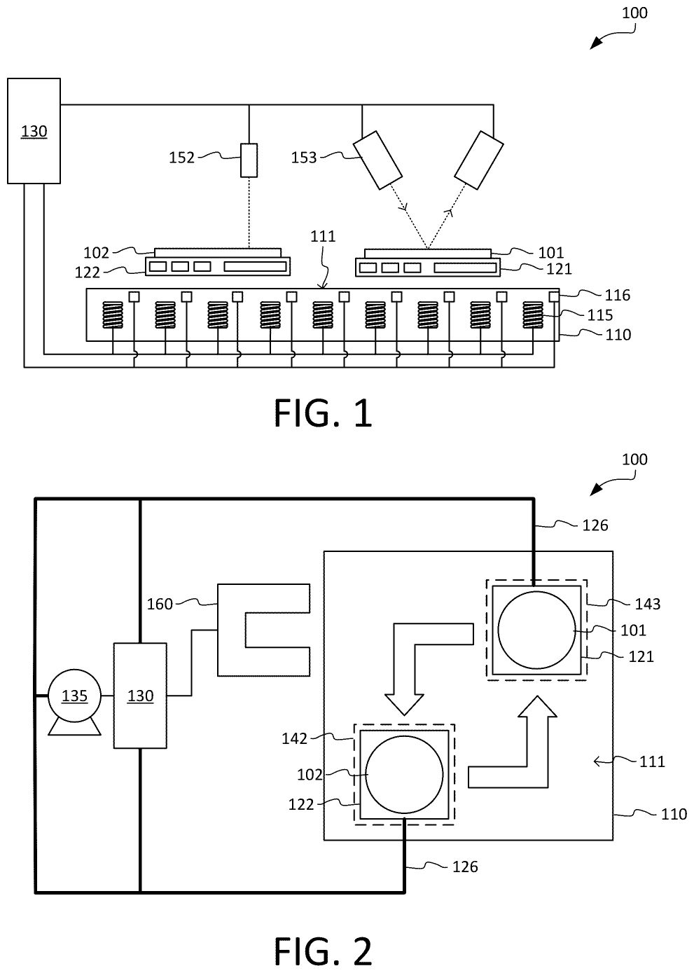

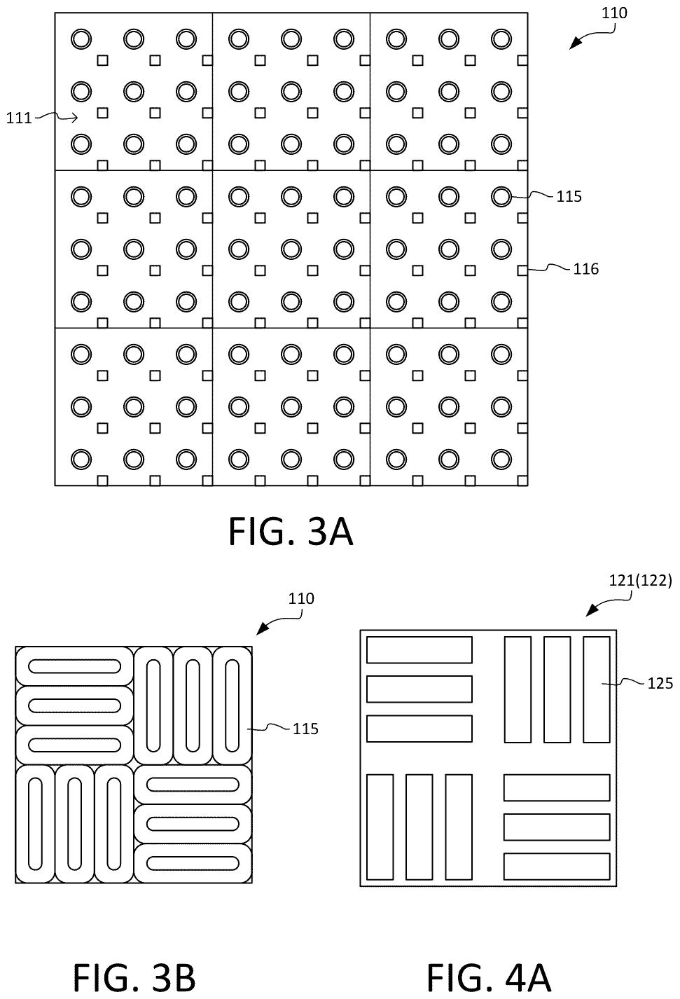

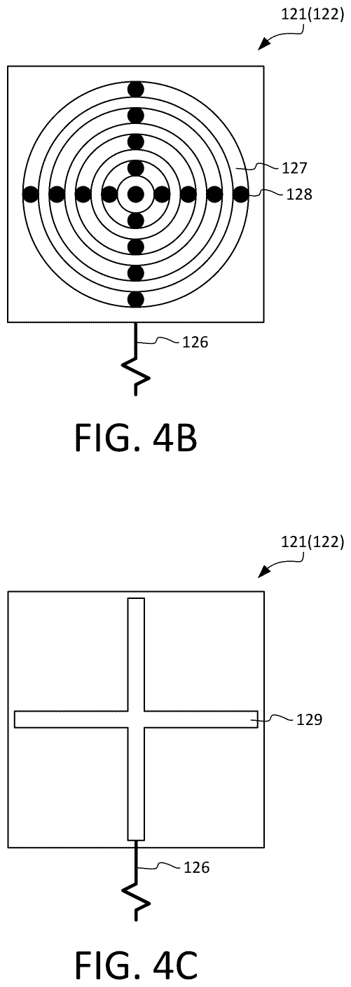

Referring to FIGS. 1-3, the system 100 may comprise a stator 110. The stator 110 may be a unitary element (e.g., the single stage shown in FIGS. 1 and 2) or a plurality of elements arranged together (e.g., the nine stage elements joined together in FIG. 3A). The stator 110 may define a horizontal surface 111. The horizontal surface 111 may be rectangular or other shapes, depending on the arrangement of the elements of the stator 110. The stator 110 may further comprise a plurality of electromagnetic coils 115 disposed in array beneath the horizontal surface 111. As shown in FIG. 3A, the plurality of electromagnetic coils 115 may be arranged in a rectangular array. The plurality of electromagnetic coils 115 may be wound cylindrically (as shown in FIG. 3A) or rectangularly (as shown in FIG. 3B). In some embodiments, the plurality of electromagnetic coils 115 may be arranged in a checkerboard pattern, in which groups of rectangularly-wound coils are arranged alternately, as shown in FIG. 3B with one stage element. The number and density of the plurality of electromagnetic coils 115 may vary and is not limited herein. When energized, each of the plurality of electromagnetic coils 115 may generate a magnetic field above the horizontal surface 111. Each of the plurality of electromagnetic coils 115 may be individually energized to selectively control the position, gradient, and strength of the magnetic field relative to the horizontal surface 111.

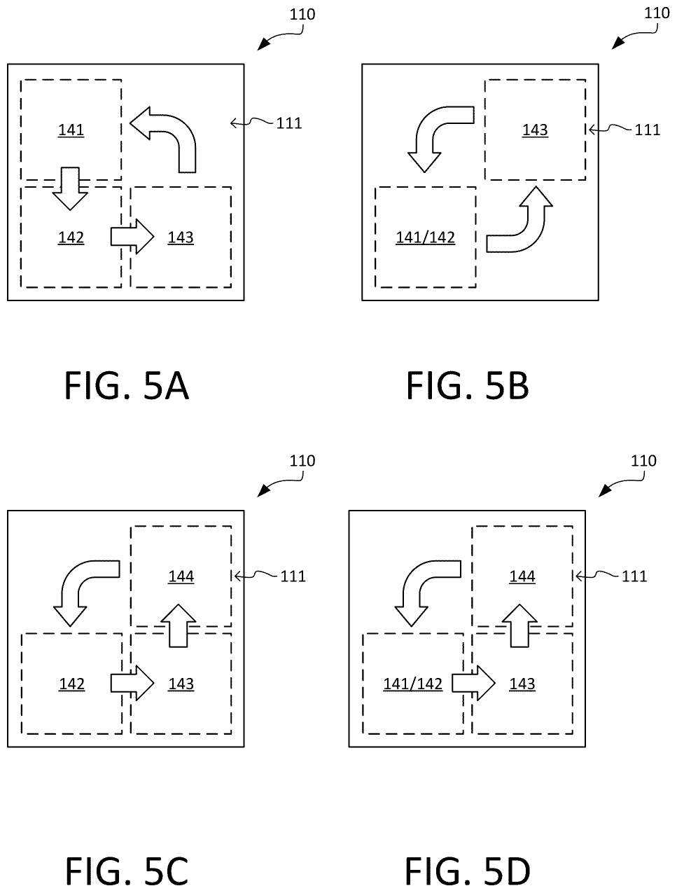

The system 100 may further comprise at least one carrier. The at least one carrier may comprise a first carrier 121 and a second carrier 122. As shown in FIGS. 1 and 2, the first carrier 121 and the second carrier 122 may be disposed over the horizontal surface 111 of the stator 110. The first carrier 121 and the second carrier 122 may be rectangular or other shapes and is not limited herein. The first carrier 121 and the second carrier 122 may be the same size and shape or different sizes/shapes. The first carrier 121 and the second carrier 122 may be smaller in area than the area of the horizontal surface 111. The first carrier 121 may be configured to support a first substrate 101, and the second carrier 122 may be configured to support a second substrate 102. The first substrate 101 and the second substrate 102 may be a workpiece such as a semiconductor wafer, substrate, printed circuit board, panel, or other object processed by the system 100. The first substrate 101 and the second substrate 102 may be circular (as shown in FIG. 2), rectangular, or other shapes. The first carrier 121 and the second carrier may each comprise a plurality of magnets 125 arranged in an array. As shown in FIG. 1, the array of the plurality of magnets 125 may be parallel to the array of the plurality of electromagnetic coils 115. The plurality of magnets 125 may be arranged in a Halbach array, as shown in FIG. 4A. A Halbach array is an arrangement of permanent magnets having a spatially rotating pattern of magnetization, which augments the magnetic field on one side of the array while cancelling the field to near zero on the other side. When in the presence of a magnetic field, such an array may cause the first carrier 121 and the second carrier 122 to move in six degrees of freedom, as further described below. It should be understood that the system 100 may include additional carriers configured similarly to the first carrier 121 and the second carrier 122, which may support additional substrates.

In some embodiments, the first carrier 121 and the second carrier 122 may each be a vacuum chuck configured to hold the first substrate 101 and the second substrate 102. Each vacuum chuck may comprise surface features 127 defined on a top surface of the first carrier 121 and the second carrier 122. The surface features 127 may be circular grooves (as shown in FIG. 4B) or other shapes and is not limited herein. A plurality of openings 128 may be disposed between the surface features, and the plurality of openings 128 may be in fluid communication with a distribution channel 129 inside each of the first carrier 121 and the second carrier 122, as shown in FIG. 4C. The distribution channel 129 may be connected to a vacuum pump 135 by a pneumatic line disposed in a flexible cable 126, as shown in FIG. 2. The flexible cable 126 may extend from the vacuum pump 135 to each of the first carrier 121 and the second carrier 122, respectively. The vacuum pump 135 may be configured to draw air from the top surface of the first carrier 121 and the second carrier 122 via the surface features 127, the plurality of openings 128, and the distribution channel 129, through the pneumatic line in the flexible cable 126. This negative pressure may hold the first substrate 101 and the second substrate 102 to the first carrier 121 and the second carrier 122, respectively.

The system 100 may further comprise a controller 130. The controller 130 may comprise at least one processor, which may include a microprocessor, a microcontroller, or other devices.

The processor may be coupled to the components of the system 100 in any suitable manner (e.g., via one or more transmission media, which may include wired and/or wireless transmission media) such that the processor can receive output. The processor may be configured to perform a number of functions using the output. An inspection tool can receive instructions or other information from the processor. The processor optionally may be in electronic communication with another inspection tool, a metrology tool, a repair tool, or a review tool (not illustrated) to receive additional information or send instructions.

The processor may be part of various systems, including a personal computer system, image computer, mainframe computer system, workstation, network appliance, internet appliance, or other device. The subsystem(s) or system(s) may also include any suitable processor known in the art, such as a parallel processor. In addition, the subsystem(s) or system(s) may include a platform with high-speed processing and software, either as a standalone or a networked tool.

The processor may be disposed in or otherwise part of the system 100 or another device. In an example, the processor and may be part of a standalone control unit or in a centralized quality control unit. Multiple processors may be used, defining multiple subsystems of the system 100.

The processor may be implemented in practice by any combination of hardware, software, and firmware. Also, its functions as described herein may be performed by one unit, or divided up among different components, each of which may be implemented in turn by any combination of hardware, software and firmware. Program code or instructions for the processor to implement various methods and functions may be stored in readable storage media, such as a memory.

If the system 100 includes more than one subsystem, then the different processors may be coupled to each other such that images, data, information, instructions, etc. can be sent between the subsystems. For example, one subsystem may be coupled to additional subsystem(s) by any suitable transmission media, which may include any suitable wired and/or wireless transmission media known in the art. Two or more of such subsystems may also be effectively coupled by a shared computer-readable storage medium (not shown).

The processor may be configured to perform a number of functions using the output of the system 100 or other output. For instance, the processor may be configured to send the output to an electronic data storage unit or another storage medium. The processor may be further configured as described herein.

The processor may be configured according to any of the embodiments described herein. The processor also may be configured to perform other functions or additional steps using the output of the system 100 or using images or data from other sources.

The processor may be communicatively coupled to any of the various components or sub-systems of system 100 in any manner known in the art. Moreover, the processor may be configured to receive and/or acquire data or information from other systems (e.g., inspection results from an inspection system such as a review tool, a remote database including design data and the like) by a transmission medium that may include wired and/or wireless portions. In this manner, the transmission medium may serve as a data link between the processor and other subsystems of the system 100 or systems external to system 100. Various steps, functions, and/or operations of system 100 and the methods disclosed herein are carried out by one or more of the following: electronic circuits, logic gates, multiplexers, programmable logic devices, ASICs, analog or digital controls/switches, microcontrollers, or computing systems. Program instructions implementing methods such as those described herein may be transmitted over or stored on carrier medium. The carrier medium may include a storage medium such as a read-only memory, a random-access memory, a magnetic or optical disk, a non-volatile memory, a solid-state memory, a magnetic tape, and the like. A carrier medium may include a transmission medium such as a wire, cable, or wireless transmission link. For instance, the various steps described throughout the present disclosure may be carried out by a single processor (or computer subsystem) or, alternatively, multiple processors (or multiple computer subsystems). Moreover, different sub-systems of the system 100 may include one or more computing or logic systems. Therefore, the above description should not be interpreted as a limitation on the present disclosure but merely an illustration.

Referring back to FIG. 1, the controller 130 may be in electronic communication with the plurality of electromagnetic coils 115 of the stator 110. The controller 130 may be configured to individually energize each of the plurality of electromagnetic coils 115, thereby controlling the strength of the magnetic field generated by each of the plurality of electromagnetic coils 115 and the position and gradient of the magnetic field across the horizontal surface 111. Energizing at least some of the plurality of electromagnetic coils 115 may cause the first carrier 121 and the second carrier 122 to levitate above the horizontal surface 111. Specifically, the controller 130 may energize the electromagnetic coils 115 disposed beneath the first carrier 121 and the second carrier 122 to generate a magnetic field beneath the first carrier 121 and the second carrier 122, and the plurality of magnets 125 disposed within the first carrier 121 and the second carrier 122 may repel the magnetic field, causing the first carrier 121 and the second carrier 122 to levitate above the horizontal surface 111. Energizing at least some of the plurality of electromagnetic coils 115 may further cause the first carrier 121 and the second carrier 122 to move relative to the horizontal surface 111 in six degrees of freedom (i.e., x, y, z directions and roll, pitch, yaw rotations). Specifically, the controller 130 may energize the electromagnetic coils 115 disposed beneath the first carrier 121 and the second carrier 122 to generate a magnetic field beneath the first carrier 121 and the second carrier 122 having a gradient or pattern relative to the four quadrants of the array of the plurality of magnets 125, and the plurality of magnets 125 disposed within the first carrier 121 and the second carrier 122 may repel the magnetic field based on the gradient or pattern, causing the first carrier 121 and the second carrier 122 to move in three planar directions and rotate in three axes relative to the horizontal surface 111, based on the arrangement of the plurality of magnets 125 in the array. For example, movement in x and y directions can be produced by controlling the magnetic field relative to two opposite quadrants of the array of the plurality of magnets 125; movement in the z direction can be produced by controlling the magnetic field relative to all four quadrants of the array of the plurality of magnets 125; roll and pitch rotation can be produced by controlling the magnetic field to have a differential between adjacent quadrants of the array of the plurality of magnets 125; and yaw rotation can be produced by controlling the magnetic field to have a differential between opposite quadrants of the array of the plurality of magnets 125. By controlling individual coils of the plurality of electromagnetic coils 115, the controller 130 may individually control the position and movement of the first carrier 121 and the second carrier 122 relative to the horizontal surface 111. The controller 130 may be calibrated to control the strength of the magnetic field generated by the plurality of electromagnetic coils 115 to lift and move the first carrier 121 and the second carrier 122 based on the parameters of the first carrier 121 and the second carrier 122 and the parameters of the first substrate 101 and the second substrate 102.

In some embodiments, the controller 130 may energize the plurality of electromagnetic coils 115 to move the first carrier 121 and the second carrier 122 in a loop relative to the horizontal surface 111. The loop may be comprised of a series of stations, each defining separate areas of the horizontal surface 111. For example, the first carrier 121 and the second carrier 122 may individually move to each station in the series of stations in the loop across the horizontal surface 111. The loop may be fixed such that the first carrier 121 and the second carrier 122 move to each of the station in the series of stations in a specified order. Alternatively, the loop may be variable such that the first carrier 121 and the second carrier 122 move to each of the station in the series of stations in different orders. In some embodiments, the loop may cause the first carrier 121 and the second carrier 122 skip some stations or repeat some stations in the loop based on feedback or processing performed on the first substrate 101 or the second substrate 102. Depending on the size of each station, both the first carrier 121 and the second carrier 122 may be positioned at a single station simultaneously or may be positioned at separate stations in the loop. The number of stations in the loop, the shape/path of the loop, and the position of each station relative to the horizontal surface 111 may depend on the arrangement of the stator 110 or the processes performed and is not limited herein.

The stator 110 may further comprise a plurality of Hall effect sensors 116, as shown in FIG. 1. The plurality of Hall effect sensors 116 may be configured to track the position of the first carrier 121 and the second carrier 122 relative to the horizontal surface 111. For example, the plurality of Hall effect sensors 116 may be arranged in an array beneath the horizontal surface 111 of the stator 110 (as shown in FIG. 3A), and the plurality of Hall effect sensors 116 may be configured to detect the proximity of the first carrier 121 or the second carrier 122 based on interaction with the plurality of magnets 125. Depending on which one(s) of the plurality of Hall effect sensors 116 detects proximity of the first carrier 121 or the second carrier 122, the positions of the plurality of Hall effect sensors 116 in the array can indicate position information of the first carrier 121 and the second carrier 122 relative to the horizontal surface 111. Each of the plurality of Hall effect sensors 116 may be in electronic communication with the controller 130. For example, each of the plurality of Hall effect sensors 116 may be connected to the controller 130 by wireless communication or by electrical wires. Based on the position information received from the plurality of Hall effect sensors 116, the controller 130 maybe configured to determine where each of the first carrier 121 and the second carrier 122 are positioned in the loop, and when each carrier is positioned at each of the series of stations in the loop.

The loop may comprise an alignment station 142. When the first carrier 121 or the second carrier 122 is positioned at the alignment station 142, the controller 130 may energize at least some of the plurality of electromagnetic coils 115 to apply a differential force to the first carrier 121 or the second carrier 122 to adjust a planar alignment of the first substrate 101 or the second substrate 102 relative to the horizontal surface 111. An interferometer 152 may be directed at the alignment station 142 of the horizontal surface 111. The controller 130 may be further configured to control the interferometer 152 to measure the planar alignment of the first substrate 101 or the second substrate 102 when the first carrier 121 or the second carrier 122 is positioned at the alignment station 142. For example, the interferometer 151 may be configured to measure the planar alignment of the first substrate 101 or the second substrate 102 by comparing the phase of light directed toward the first substrate 101 or the second substrate 102 with the phase of light reflected by the first substrate 101 or the second substrate 102. Such a phase shift can indicate a planar alignment that is horizontal or has local tilt. The controller 130 may be further configured to determine the planar alignment of the first substrate 101 or the second substrate 102 based on the respective alignment information received from the interferometer 152. The controller 130 may be further configured to energize at least some of the plurality of electromagnetic coils 115 to apply a differential force to the first carrier 121 or the second carrier 122 to adjust the planar alignment of the first substrate 101 or the second substrate 102 to an adjusted planar alignment, thereby correcting local tilt.

The loop may further comprise a measurement station 143. The controller 130 may determine whether the first carrier 121 or the second carrier 122 is positioned at the measurement station 143 based on the position information received from the plurality of Hall effect sensors 116. When the first carrier 121 or the second carrier 122 is positioned at the measurement station 143, the controller 130 may control a metrology tool 153 to take one or more measurements of the first substrate 101 or the second substrate 102. The metrology tool 153 may be configured to capture measurements based on at least one or reflectometry, spectroscopy, ellipsometry, or image data.

In the adjusted planar alignment, the first substrate 101 and the second substrate 102 may be substantially horizontal, so as to improve accuracy of measurements made by the metrology tool 153 when the first carrier 121 and the second carrier 122 are positioned at the measurement station 143. It should be understood that the differential force used to adjust the planar alignment to the adjusted planar alignment may differ between substrates, thus the measurement at the alignment station 142 may provide feedback to place the first carrier 121 and the second carrier 122 in adjusted positions before being measured at the measurement station 143. The controller 130 may be configured to record the differential force used to adjust each of the first carrier 121 and the second carrier 122 to the adjusted planar alignment, to be used with subsequent movements of the first carrier 121 and the second carrier 122 in the loop. Accordingly, the first substrate 101 and the second substrate 102 may remain in the adjusted planar alignment when moved in the loop from the alignment station 142 to the measurement station 143.

The system 100 may further comprise a handling robot 160, as shown in FIG. 2. The handling robot 160 may be configured to load the first substrate 101 on the first carrier 121 and load the second substrate 102 on the second carrier 122. The loop may further comprise a load station 141, and the handling robot 160 may be configured to load the first substrate 101 on the first carrier 121 when the first carrier 121 is positioned at the load station 141 and load the second substrate 102 on the second carrier 122 when the second carrier 122 is positioned at the load station 141. The controller 130 may be configured to control the handling robot 160 to move relative to the stator 110 in order to load the first substrate 101 on the first carrier 121 and load the second substrate 102 on the second carrier 122. The controller 130 may be further configured to control the vacuum pump 135 to draw air from the first carrier 121 and the second carrier 122 to hold the first substrate 101 and the second substrate 102 after being loaded by the handling robot 160.

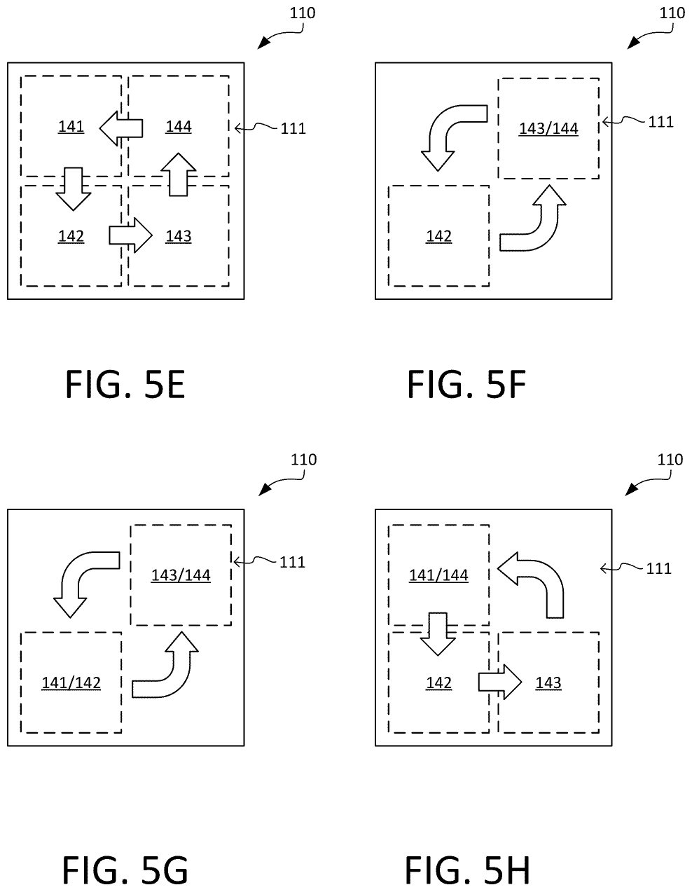

In some embodiments, the load station 141 may define an area of the horizontal surface 111 in the loop separate from the alignment station 142 and the measurement station 143. In other words, the series of stations in the loop may include at least three stations: the load station 141, the alignment station 142, and the measurement station 143, as shown in FIG. 5A.

In some embodiments, the load station 141 may be the alignment station 142. In other words, the load station 141 and the alignment station 142 may define the same area of the horizontal surface 111 in the loop separate from the measurement station 143. The first substrate 101 and the second substrate 102 may therefore be loaded directly for the alignment process. Accordingly, the series of stations in the loop may include at least two stations: the combined load station 141 and alignment station 142 and the measurement station 143, as shown in FIG. 5B.

The handling robot 160 may be further configured to unload the first substrate 101 from the first carrier 121 and unload the second substrate 102 from the second carrier 122. The loop may further comprise an unload station 144, and the handling robot 160 may be configured to unload the first substrate 101 from the first carrier 121 when the first carrier 121 is positioned at the unload station 144 and unload the second substrate 102 from the second carrier 122 when the second carrier 122 is positioned at the unload station 144. The controller 130 may be configured to control the handling robot 160 to move relative to the stator 110 in order to unload the first substrate 101 from the first carrier 121 and unload the second substrate 102 from the second carrier 122. The controller 130 may be further configured to control the vacuum pump 135 to turn off to stop drawing air from the first carrier 121 and the second carrier 122 to release the first substrate 101 and the second substrate 102 before being unloaded by the handling robot 160.

In some embodiments, the unload station 144 may define an area of the horizontal surface 111 in the loop separate from the alignment station 142 and the measurement station 143. In other words, the series of stations in the loop may include at least three stations: the alignment station 142, the measurement station 143, and the unload station 144 (as shown in FIG. 5C) or the combined load station 141 and alignment station 142, the measurement station 143, and the unload station 144 (as shown in FIG. 5D).

In some embodiments, the unload station 144 may further define an area of the horizontal surface 111 in the loop separate from the load station 141. In other words, the series of stations in the loop may include at least four stations: the load station 141, the alignment station 142, the measurement station 143, and the unload station 144, as shown in FIG. 5E.

In some embodiments, the unload station 144 may be the measurement station 143. In other words, the unload station 144 and the measurement station 143 may define the same area of the horizontal surface 111 in the loop separate from the alignment station 142. The first substrate 101 and the second substrate 102 may therefore be unloaded directly after the measurement process. Accordingly, the series of stations in the loop may include at least two stations: the alignment station 142 and the combined measurement station 143 and unload station 144 (as shown in FIG. 5F), or the combined load station 141 and alignment station 142 and the combined measurement station 143 and unload station 144 (as shown in FIG. 5G).

In some embodiments, the unload station 144 may be the load station 141. In other words, the unload station 144 and the load station 141 may define the same area of the horizontal surface 111 in the loop separate from the alignment station 142 and the measurement station 143. The handling robot 160 may therefore load and unload the first substrate 101 and the second substrate 102 from the same position away from the alignment and measurement processes. Accordingly, the series of stations in the loop may include at least three stations: the combined load station 141 and unload station 144, the alignment station 142, and the measurement station 143, as shown in FIG. 5H.

The series of stations in the loop may be continuous. For example, the area of the horizontal surface 111 that defines the load station 141 may abut the area of the horizontal surface 111 that defines the alignment station 142. Accordingly, the area of the horizontal surface 111 may be minimized to include the areas that define the series of station in the loop. Alternatively, the series of station in the loop may be spaced apart. For example, the area of the horizontal surface 111 that defines the alignment station 142 may be spaced apart from the area of the horizontal surface that defines that measurement station 143. Accordingly, the area of the horizontal surface 111 may accommodate parallel processing of additional carriers, as they can be positioned between stations while other carriers are being processed, and interference between adjacent processes and handling may be avoided.

In an example, the controller 130 may be configured to move the first carrier 121 and the second carrier 122 in the loop in a sequence from the load station 141 to the alignment station 142, from the alignment station 142 to the measurement station 143, from the measurement station 143 to the unload station 144, and from the unload station 144 to the load station 141. It should be understood that the sequence may change based on the number of stations in the series of stations, some of which may serve dual functions as described above. The sequence may also change to operate in reverse (e.g., to move from the measurement station 143 back to the alignment station 142 for realignment), repeat stations, or skip stations and is not limited herein.

The system 100 can comprise one or more hardware configurations which may be used in conjunction with certain embodiments of this invention to, for example, measure the various aforementioned semiconductor structural and material characteristics. Examples of such hardware configurations include, but are not limited to, a spectroscopic ellipsometer (SE), an SE with multiple angles of illumination, an SE measuring Mueller matrix elements (e.g. using rotating compensator(s)), a single-wavelength ellipsometer, a beam profile ellipsometer (angle-resolved ellipsometer), a beam profile reflectometer (angle-resolved reflectometer), a broadband reflective spectrometer (spectroscopic reflectometer), a single-wavelength reflectometer, an angle-resolved reflectometer, an imaging system, or a scatterometer (e.g. speckle analyzer).

The hardware configurations can be separated into discrete operational systems. One or more hardware configurations can be combined into a single tool. U.S. Pat. No. 7,933,026, which is hereby incorporated by reference in its entirety, provides an example. There are typically numerous optical elements in such systems, including certain lenses, collimators, mirrors, quarter-wave plates, polarizers, detectors, cameras, apertures, and/or light sources. The wavelengths for optical systems can vary from about 120 nm to 3 microns. For non-ellipsometer systems, signals collected can be polarization-resolved or unpolarized. Multiple metrology tools also can be used for measurements on a single or multiple metrology targets, such as described in U.S. Pat. No. 7,478,019, which is incorporated by reference in its entirety.

The illumination system of the certain hardware configurations can include one or more light sources. The light source may generate light having only one wavelength (i.e., monochromatic light), light having a number of discrete wavelengths (i.e., polychromatic light), light having multiple wavelengths (i.e., broadband light) and/or light the sweeps through wavelengths, either continuously or hopping between wavelengths (e.g., using tunable sources or swept source). Examples of suitable light sources include a white light source, an ultraviolet (UV) laser, an arc lamp or an electrode-less lamp, a laser sustained plasma (LSP) source, a supercontinuum source (such as a broadband laser source), or shorter-wavelength sources such as x-ray sources, extreme UV sources, or some combination thereof. The light source may also be configured to provide light having sufficient brightness, which in some cases may be a brightness greater than about 1 W/(nm cm² Sr). The system 100 also can include a fast feedback to the light source for stabilizing its power and wavelength. Output of the light source can be delivered via free-space propagation, or in some cases delivered via optical fiber or light guide of any type.

The system 100 can be designed to make many different types of measurements related to semiconductor manufacturing. For example, the system 100 can measure characteristics of one or more targets, such as critical dimensions, overlay, sidewall angles, film thicknesses, process-related parameters (e.g., focus and/or dose). The targets can include certain regions of interest that are periodic in nature, such as for example gratings in a memory die. Targets can include multiple layers (or films) whose thicknesses can be measured by the metrology tool. Targets can include target designs placed (or already existing) on the semiconductor wafer for use, such as with alignment and/or overlay registration operations. Certain targets can be located at various places on the semiconductor wafer. For example, targets can be located within the scribe lines (e.g., between dies) and/or located in the die itself. In certain embodiments, multiple targets are measured (at the same time or at differing times) by the same or multiple metrology tools. The data from such measurements may be combined. Data from the system 100 can be used in the semiconductor manufacturing process for example to feed-forward, feed-backward and/or feed-sideways corrections to the process (e.g., lithography or etch).

As semiconductor device pattern dimensions continue to shrink, smaller metrology targets are often required. Furthermore, the measurement accuracy and matching to actual device characteristics can increase the need for device-like targets as well as in-die and even on-device measurements. For example, focused beam ellipsometry based on primarily reflective optics can be used. Apodizers can be used to mitigate the effects of optical diffraction causing the spread of the illumination spot beyond the size defined by geometric optics. High-numerical-aperture tools with simultaneous multiple angle-of-incidence illumination can be used to achieve small-target capability.

Other measurement examples can include measuring the composition of one or more layers of the semiconductor stack, measuring certain defects on (or within) the wafer, or measuring the amount of photolithographic radiation exposed to the wafer. In some cases, the system 100 and algorithm may be configured for measuring non-periodic targets.

In addition, there are typically numerous optical elements in such systems, including certain lenses, collimators, mirrors, quarter-wave plates, polarizers, detectors, cameras, apertures, and/or light sources. The wavelengths for optical systems can vary from about 120 nm to 3 microns. For non-ellipsometer systems, signals collected can be polarization-resolved or unpolarized. Multiple metrology heads can be integrated on the same tool. However, in many cases, multiple metrology tools are used for measurements on a single or multiple metrology targets.

Measurement of parameters of interest usually involves multiple algorithms. For example, optical interaction of the incident beam with the sample is modeled using an electro-magnetic (EM) solver and uses such algorithms as rigorous coupled wave analysis (RCWA), finite element modeling (FEM), method of moments, surface integral method, volume integral method, finite-difference time domain (FDTD), and others. The target of interest is usually modeled (parametrized) using a geometric engine a process modeling engine, or a combination of both. A geometric engine is implemented, for example, in the AcuShape software product from KLA Corporation.

Collected data can be analyzed by a number of data fitting and optimization techniques and technologies including libraries, fast-reduced-order models, regression, machine-learning algorithms, principal component analysis (PCA), independent component analysis (ICA), local-linear embedding (LLE), sparse representation such as Fourier or wavelet transform, a Kalman filter, algorithms to promote matching from same or different tool types, or others. Collected data can also be analyzed by algorithms that do not include modeling, optimization and/or fitting.

Computational algorithms are usually optimized for metrology applications with one or more approaches being used such as design and implementation of computational hardware, parallelization, distribution of computation, load-balancing, multi-service support, or dynamic load optimization. Different implementations of algorithms can be done in firmware, software, FPGA, programmable optics components, etc.

The data analysis and fitting steps can have one or more objectives. Critical dimension, sidewall angle, shape, stress, composition, films, bandgap, electrical properties, focus/dose, overlay, generating process parameters (e.g., resist state, partial pressure, temperature, focusing model), and/or any combination thereof can be measured or otherwise determined. Metrology systems can be modeled or designed. Metrology targets also can be modelled, designed, and/or optimized.

Embodiments of the present disclosure address the field of semiconductor metrology and are not limited to the hardware, algorithm/software implementations and architectures, and use cases summarized above.

With the system 100, throughput may be increased as multiple substrates can be processed in parallel. In particular, the second substrate 102 can be loaded and aligned at the alignment station 142, while the first substrate 101 is measured at the measurement station 143. The arrangement of planar motors of the stator 110, the first carrier 121, and the second carrier 122 may have higher acceleration and velocity compared to stacked or gantry stage arrangements, which can further improve system throughput. Applying a differential force to the levitating first carrier 121 and second carrier 122 may allow accurate planar adjustment in six degrees of freedom for micron level applications.

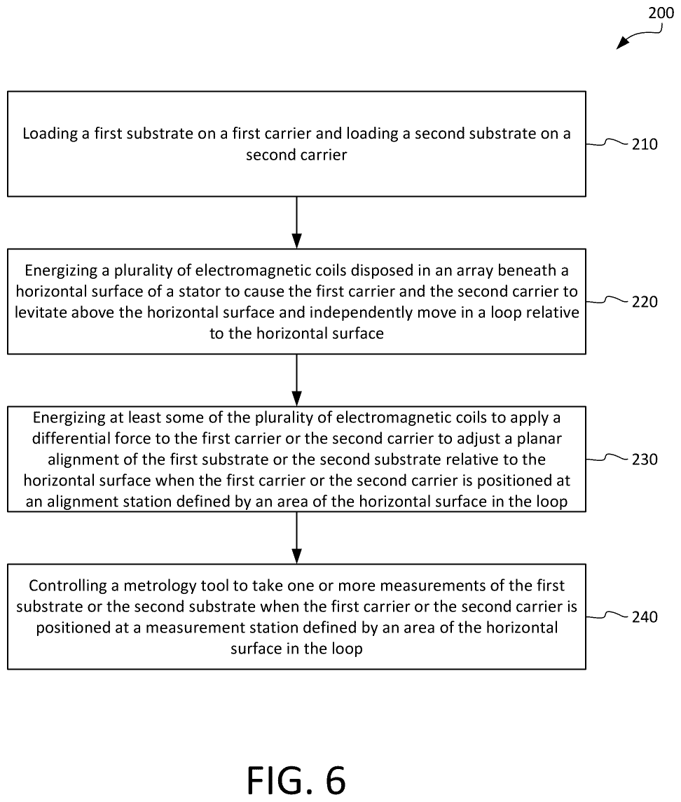

Another embodiment of the present disclosure provides a method 200. As shown in FIG. 6, the method 200 may comprise the following steps.

At step 210, a first substrate is loaded on a first carrier, and a second substrate is loaded on a second carrier. The first carrier and the second carrier each comprise plurality of magnets arranged in an array, and the first carrier and the second carrier are disposed over a horizontal surface of a stator. Additional carriers may be used to load additional substrates into the system. A handling robot may be used to load and unload substrates from each carrier.

At step 220, a plurality of electromagnetic coils disposed in an array beneath the horizontal surface are energized to cause the first carrier and the second carrier to levitate above the horizontal surface and independently move in a loop relative to the horizontal surface. A measurement station and an alignment station each define separate areas of the horizontal surface in the loop.

At step 230, at least some of the plurality of electromagnetic coils are energized to apply a differential force to the first carrier or the second carrier to adjust a planar alignment of the first substrate or the second substrate relative to the horizontal surface when the first carrier or the second carrier is positioned at the alignment station.

At step 240, a metrology tool is controlled to take one or more measurements of the first substrate or the second substrate when the first carrier or the second carrier is positioned at the measurement station.

After step 240, the first substrate or the second substrate may be unloaded from the first carrier or the second carrier, and step 210 may be repeated to load another substrate onto the first carrier and the second carrier for continued processing.

In an instance, the first substrate is loaded on the first carrier before the second substrate is loaded on the second carrier, and the second substrate is loaded on the second carrier while the first carrier is positioned at the alignment station or the measurement station. Accordingly, the first substrate and the second substrate may be processed in parallel.

In an instance, a plurality of Hall effect sensors may be used to track the positions of the first carrier and the second carrier relative to the horizontal surface. The position information may be used to determine whether the first carrier and the second carrier is positioned at the alignment station and the measurement station. Accordingly, step 230 may be performed after determining that the first carrier or the second carrier is positioned at the alignment station, and step 240 may be performed after determining that the first carrier or the second carrier is positioned at the measurement station.

With the method 200, throughput may be increased as multiple substrates can be processed in parallel. In particular, the second substrate can be loaded and aligned at the alignment station, while the first substrate is measured at the measurement station. The arrangement of planar motors of the stator, the first carrier, and the second carrier may have higher acceleration and velocity compared to stacked or gantry stage arrangements, which can further improve system throughput. Applying a differential force to the levitating first carrier and second carrier may allow accurate planar adjustment in six degrees of freedom for micron level applications.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. A system comprising:
a stator comprising a horizontal surface and a plurality of electromagnetic coils disposed in an array beneath the horizontal surface;
a first carrier and a second carrier disposed over the horizontal surface of the stator, wherein the first carrier and the second carrier each comprise plurality of magnets arranged in an array, and the first carrier and the second carrier are configured to support a first substrate and a second substrate, respectively;
a controller configured to individually energize each of the plurality of electromagnetic coils, wherein energizing at least some of the plurality of electromagnetic coils causes the first carrier and the second carrier to levitate above the horizontal surface and independently move in a loop relative to the horizontal surface; and
an alignment station and a measurement station, each defining separate areas of the horizontal surface in the loop;
wherein the controller is further configured to:
energize at least some of the plurality of electromagnetic coils to apply a differential force to the first carrier or the second carrier to adjust a planar alignment of the first substrate or the second substrate relative to the horizontal surface when the first carrier or the second carrier is positioned at the alignment station; and
control a metrology tool to take one or more measurements of the first substrate or the second substrate when the first carrier or the second carrier is positioned at the measurement station.

2. The system of claim 1, wherein the plurality of magnets is arranged in a Halbach array.

3. The system of claim 1, further comprising a vacuum pump, wherein the first carrier and the second carrier are configured to hold the first substrate or the second substrate by vacuum pressure from the vacuum pump.

4. The system of claim 3, wherein the first carrier and the second carrier each further comprise:
surface features defined on a top surface beneath the first substrate or the second substrate;
a plurality of openings disposed between the surface features; and
a distribution channel in fluid communication with the plurality of openings;
wherein the vacuum pump is connected to the distribution channel by a flexible cable and is configured to draw air from the top surface of the first carrier and the second carrier via the surface features, the plurality of openings, and the distribution channel, through a pneumatic line in the flexible cable.

5. The system of claim 1, wherein the stator further comprises a plurality of Hall effect sensors arranged in an array beneath the horizontal surface, wherein the plurality of Hall effect sensors are configured to track positions of the first carrier and the second carrier relative to the horizontal surface.

6. The system of claim 5, wherein the plurality of Hall effect sensors are configured to track the positions of the first carrier and the second carrier based on proximity of the plurality of magnets of the first carrier and the second carrier to at least one of the plurality of Hall effect sensors.

7. The system of claim 5, wherein the controller is further configured to:
determine whether the first carrier or the second carrier is positioned at the measurement station based on position information received from the plurality of Hall effect sensors;
control the metrology tool to take one or more measurements of the first substrate when the first carrier is determined to be positioned at the measurement station; and
control the metrology tool to take one or more measurements of the second substrate when the second carrier is determined to be positioned at the measurement station.

8. The system of claim 1, wherein the metrology tool is configured to capture measurements based on at least one of reflectometry, spectroscopy, ellipsometry, image data.

9. The system of claim 1, further comprising a handling robot, wherein the handling robot is configured to:
load the first substrate on the first carrier when the first carrier is positioned at a load station; and
load the second substrate on the second carrier when the second carrier is positioned at the load station.

10. The system of claim 9, wherein the load station defines an area of the horizontal surface in the loop separate from the alignment station and the measurement station, and the controller is further configured to:
determine whether the first carrier or the second carrier is positioned at the load station based on position information received from a plurality of Hall effect sensors; and
energize at least some of the plurality of electromagnetic coils to move the first carrier and the second carrier in the loop from the load station to the alignment station or the measurement station.

11. The system of claim 9, wherein the load station is the alignment station.

12. The system of claim 9, wherein the handling robot is further configured to:
unload the first substrate from the first carrier when the first carrier is positioned at an unload station; and
unload the second substrate from the second carrier when the second carrier is positioned at the unload station.

13. The system of claim 12, wherein the unload station defines an area of the horizontal surface separate from the alignment station and the measurement station, and the controller is further configured to:
energize at least some of the plurality of electromagnetic coils to move the first carrier and the second carrier in the loop from the alignment station or the measurement station to the unload station; and
determine whether the first carrier or the second carrier is positioned at the unload station based on the position information received from the plurality of Hall effect sensors.

14. The system of claim 12, wherein the unload station is the measurement station.

15. The system of claim 12, wherein the unload station is the load station.

16. The system of claim 1, wherein the controller is further configured to control an interferometer to measure the planar alignment of the first substrate or the second substrate when the first carrier or the second carrier are positioned at the alignment station.

17. The system of claim 16, wherein the controller is further configured to:
determine the planar alignment of the first substrate or the second substrate based on alignment information received from the interferometer; and
energize at least some of the plurality of electromagnetic coils to apply the differential force to the first carrier or the second carrier to adjust the planar alignment of the first substrate or the second substrate to an adjusted planar alignment.

18. The system of claim 17, wherein the first substrate and the second substrate remain in the adjusted planar alignment when moved in the loop from the alignment station to the measurement station.

19. A method comprising:
loading a first substrate on a first carrier and a second substrate on a second carrier, wherein the first carrier and the second carrier each comprise plurality of magnets arranged in an array, and the first carrier and the second carrier are disposed over a horizontal surface of a stator;
energizing a plurality of electromagnetic coils disposed in an array beneath the horizontal surface to cause the first carrier and the second carrier to levitate above the horizontal surface and independently move in a loop relative to the horizontal surface, wherein a measurement station and an alignment station each define separate areas of the horizontal surface in the loop;
energizing at least some of the plurality of electromagnetic coils to apply a differential force to the first carrier or the second carrier to adjust a planar alignment of the first substrate or the second substrate relative to the horizontal surface when the first carrier or the second carrier is positioned at the alignment station; and
controlling a metrology tool to take one or more measurements of the first substrate or the second substrate when the first carrier or the second carrier is positioned at the measurement station.

20. The method of claim 19, wherein the first substrate is loaded on the first carrier before the second substrate is loaded on the second carrier, and the second substrate is loaded on the second carrier while the first carrier is positioned at the alignment station or the measurement station.
